(19) United States
(12) Patent Application Publication
(10) Pub. No.: US 2020/0292940 A1
(43) Pub. Date: Sep. 17, 2020

(54) SILSESQUIOXANE COMPOSITION WITH BOTH POSITIVE AND NEGATIVE PHOTO RESIST CHARACTERISTICS

(71) Applicant: Dow Silicones Corporation, Midland, MI (US)

(72) Inventors: Kai Su, Midland, MI (US); Karmen Asch, Beaverton, MI (US); Brandon W. Swatowski, Sanford, MI (US); Jon Degroot, JR., Midland, MI (US)

(21) Appl. No.: 16/621,978

(22) PCT Filed: Jun. 15, 2018
(86) PCT No.: PCT/US2018/037679

§ 371 Date: Dec. 12, 2019

Related U.S. Application Data
(60) Provisional application No. 62/538,420, filed on Jul. 28, 2017.

(51) Int. Cl. G03F 7/075; G03F 7/004

(52) U.S. Cl. CPC G03F 7/0757; G03F 7/162; G03F 7/0045

(57) ABSTRACT

This invention pertains to a photo sensitive composition that can be used as both positive and negative photo resist comprising: (A) a siloxane resin composition comprising 0 to 95 mole present of R¹SiO_{3/2} siloxane units, 0 to 95 mole percent of R²SiO_{3/2} siloxane units, and 1 to 99.9 mole percent of (R³O)_{b}SiO_{(4-b)/2} siloxane units wherein R¹ is hydrogen, an alkyl group containing 1 to 20 carbon atoms, or an aromatic group containing 1 to 20 carbon atoms, R² is a fluoroalkyl group containing 1 to 20 carbon atoms, R³ is independently selected from the group consisting of branched alkyl groups containing 3 to 30 carbon atoms, b has a value of 1 to 3, and wherein the siloxane resin composition the siloxane resin contains a molar ratio of R¹SiO_{3/2}+R²SiO_{3/2} siloxane units to (R³O)_{b}SiO_{(4-b)/2} siloxane units of 1:99 to 99:1 and wherein the sum of R¹SiO_{3/2} siloxane units, R²SiO_{3/2} siloxane units, and (R³O)_{b}SiO_{(4 b)/2} siloxane units is at least 5 mole percent of the total siloxane units in the resin composition; (B) a photo acid generator (PAG); and (C) an organic solvent. This invention further relates to a process to make patterned structures from these resins by using either a positive or a negative mask by a UV lithography process.

### CROSS-REFERENCE TO RELATED APPLICATIONS

This application claims the benefit of U.S. Provisional Patent Application Ser. No. 62/538,420 filed on 28 Jul. 2017 under 35 U.S.C. § 119 (e). U.S. Provisional Patent Application Ser. No. 62/538,420 is hereby incorporated by reference

### BACKGROUND OF THE INVENTION

Photoresist is commonly used for IC manufacturing to produce patterned structure. A photo resist is photosensitive polymer that masks portion of substrate and produces structure through exposure to high energy radiation, followed by the development process, which will remove part of the films. The material is called a positive photo resist when the UV exposed region is removed by the development process. The material is typically called negative photo resist when the UV exposed regions is removed by the development process. Photo resist is typically either a positive or negative resist. It is uncommon to have a material that can function as both a positive or a negative resist based on the processing conditions.

Building faster and smaller processors calls for resists that meet requirements including high transparency, good adhesion to the substrate materials, good thermal stability and higher etch resistance. 193 nm (ArF) immersion lithography and 157 nm (F2) lithography are widely investigated and rapidly emerging as viable technologies for sub-65 nm node devices. The thickness of the imaging layer tends to be thinner for higher resolution and it is desired to have a larger process window for the development step. This requires developing photoresist with ultrahigh etching resistance. Although both fluorocarbon polymers and silicon-containing polymers including silsesquioxanes have shown high transparency at 157 nm, the silicon containing materials, especially silsesquioxane-based resists, have an advantage of being highly resistant to plasma etch and suitable for bilayer photoresist application.

### BRIEF SUMMARY OF THE INVENTION

This invention pertains to a photo sensitive composition that can be used as both a positive and a negative photo resist comprising:
(A) a siloxane resin composition comprising 0 to 95 mole present of R¹SiO_{3/2} siloxane units, 0 to 95 mole percent of R²SiO_{3/2} siloxane units, and 1 to 99.9 mole percent of (R³O)_{b}SiO_{(4-b)/2} siloxane units wherein R¹ is hydrogen, an alkyl group containing 1 to 20 carbon atoms, or an aromatic group containing 1 to 20 carbon atoms, R² is a fluoroalkyl group containing 1 to 20 carbon atoms, R³ is independently selected from the group consisting of branched alkyl groups containing 3 to 30 carbon atoms, b has a value of 1 to 3, and wherein the siloxane resin composition the siloxane resin contains a molar ratio of R¹SiO_{3/2}+R²SiO_{3/2} siloxane units to (R³O)_{b}SiO_{(4-b)/2} siloxane units of 1:99 to 99:1 and wherein the sum of R¹SiO_{3/2} siloxane units, R²SiO_{3/2} siloxane units, and (R³O)_{b}SiO_{(4-b)/2} siloxane units is at least 5 mole percent of the total siloxane units in the resin composition;
(B) a photo acid generator (PAG); and
(C) an organic solvent.

This invention further relates to a process to make patterned structures from these resins by using either a positive or a negative mask in an ultraviolet (UV) lithography process. In the case of using the above formulation as a negative resist, the film is patterned with a negative mask, and then baked at temperature and duration such that the region exposed to UV light is cured and becomes insoluble during the solvent development process. In general, a high baking temperature (>100° C.) is required (specific conditions depend upon the particular resin composition used) for the material to function as a negative resist. For use as a positive resist, the film is cured with UV light, followed by a bake at a temperature that promotes decomposition of the branched alkyl group to form silanol, but not to the extent that the UV exposed region is crosslinked and becomes insoluble. The formation of a silanol group leads to a change of solubility of the materials in the UV exposed region and a suitable solvent can be chosen to selectively remove the material. As a result, a positive pattern is generated.

### DETAILED DESCRIPTION OF THE INVENTION

In the siloxane resin composition (A), R¹ is hydrogen, an alkyl group containing 1 to 20 carbon atoms, or an aromatic group containing 1 to 20 carbon atoms. The alkyl group containing 1 to 20 carbon atoms is exemplified by alkyl groups such as methyl, ethyl, propyl, butyl, hexyl, octyl, and decyl, or cycloaliphatic radicals such as cyclohexyl. The aromatic group containing 1 to 20 carbon atoms is exemplified by phenyl, tolyl, and xylyl, or aralkyl groups such as benzyl and phenylethyl. Alternatively R¹ is selected from methyl, phenyl, hydrogen or mixtures thereof.

In the siloxane resin composition (A), R² is a fluoroalkyl group containing 1 to 20 carbon atoms which is exemplified by fluoroalkyl groups having the formula —(CH₂)ₘCF₃, and —(CH₂)ₘ(CF₂)ₙCF₃, where m has a value of from 1 to 19, and n has a value of from 1 to 18, wherein the total value of m+n is from 1 to 19. The fluoroalkyl group R² is exemplified by —(CH₂)₂CF₃ and —(CH₂)₂(CF₂)₅CF₃.

In the siloxane resin composition (A), R³ is a substituted or unsubstituted branched alkyl group having 3 to 30 carbon atoms. The substituted branched alkyl group can be substituted with substituents in place of a carbon bonded hydrogen atom (C—H). Substituted R³ groups are exemplified by, but not limited to, halogen such as chlorine and fluorine, alkoxycarbonyl such as described by formula —(CH₂)ₐC(O)O(CH₂)_{b}CH₃, alkoxy substitution such as described by formula —(CH₂)ₐO(CH₂)_{b}CH₃, and carbonyl substitution such as described by formula —(CH₂)ₐC(O)(CH₂)_{b}CH₃, where a and b are both greater than or equal to zero. Unsubstituted R³ groups are exemplified by, but not limited to, isopropyl, isobutyl, sec-butyl, tert-butyl, isopentyl, neopentyl, tert-pentyl, 2-methylbutyl, 2-methylpentyl, 2-methylhexyl, 2-ethylbutyl, 2-ethylpentyl, and 2-ethylhexyl. Alternatively R³ is a tertiary alkyl group having 4 to 18 carbon atoms including where R³ is tertiary (tert) butyl group.

In other embodiments the siloxane resin composition (A) can contain 5 to 95 mole percent of R¹SiO_{3/2} siloxane units, 5 to 95 mole percent of R²SiO_{3/2} siloxane units, and 1 to 99.9 mole percent of (R³O)_{b}SiO_{(4-b)/2} siloxane units.

The structure of the siloxane resin is not specifically limited. The siloxane resins may be essentially fully condensed or may be only partially reacted (i.e., containing less than 10 mole % Si—OR and/or less than 30 mole % Si—OH). The partially reacted siloxane resins may be exemplified by, but not limited to, siloxane units such as R¹Si(X)_{d}O_{(3-d/2)}, R²Si(X)_{d}O_{(3-d/2)}, and Si(X)_{d}(OR³)_{f}O_{(4-d-f/2)}, in which R¹, R², and R³ are defined above; each X is independently a hydrolyzable group or a hydroxy group, and d and f are from 1 to 2. The hydrolyzable group is an organic group attached to a silicon atom through an oxygen atom (Si—OR) forming a silicon bonded alkoxy group or a silicon bonded acyloxy group. R is exemplified by, but not limited to, linear alkyl groups having 1 to 6 carbon atoms such as methyl, ethyl, propyl, butyl, pentyl, or hexyl and acyl groups having 1 to 6 carbon atoms such as formyl, acetyl, propionyl, butyryl, valeryl or hexanoyl. The siloxane resin may also contain less than about 10 mole percent SiO_{4/2} units.

The siloxane resins have a weight average molecular weight in a range of 400 to 160,000 and alternatively in a range of 5,000 to 100,000.

The photo acid generator (PAG), ingredient (B) is a compound that generates acid upon exposure to radiation. This acid then causes the acid dissociable group in the silsesquioxane resin to dissociate. Acid generators are well known in the art and are described in, for example, EP1142928 A1. Acid generators may be exemplified by, but not limited to, onium salts, halogen-containing compounds, diazoketone compounds, sulfone compounds, sulfonate compounds and others. Examples of onium salts include, but are not limited to, iodonium salts, sulfonium salts (including tetrahydrothiophenium salts), phosphonium salts, diazonium salts, and pyridinium salts.

Photo-acid generators may be exemplified by, but not limited to, onium salts, halogen-containing compounds, diazoketone compounds, sulfone compounds, sulfonate compounds and others. Examples of onium salts include, but are not limited to, iodonium salts, sulfonium salts (including tetrahydrothiophenium salts), phosphonium salts, diazonium salts, and pyridinium salts. Examples of halogen-containing compounds include, but are not limited to, mahaloalkyl group-containing hydrocarbon compounds, haloalkyl group-containing heterocyclic compounds, and others. Examples of diazoketone compounds include, but are not limited to, 1,3-diketo-2-diazo compounds, diazobenzoquinone compounds, diazonaphthoquinone compounds, and others. Examples of sulfone compounds, include, but are not limited to, .beta.-ketosulfone, .beta.-sulfonylsulfone, .alpha.-diazo compounds of these compounds, and others. Examples of sulfonate compounds include, but are not limited to, alkyl sulfonate, alkylimide sulfonate, haloalkyl sulfonate, aryl sulfonate, imino sulfonate, and others. The photo-acid generator (B) may be used either individually or in combination of two or more. The preferred acid generators are sulfonated salts, in particular sulfonated salts with perfluorinated methide anions. The amount of (B) in the photo sensitive composition is typically in the range of 0.1 to 8 parts by weight based on 100 parts of (A), the siloxane resin composition, and alternatively 0.42 to 35 parts by weight based on 100 parts of (A).

Component (C) in the composition is an organic solvent. The choice of solvent is governed by many factors such as the solubility and miscibility of the siloxane resin composition and photo-acid generator, the coating process and safety and environmental regulations. Typical solvents include ether-, ester-, hydroxyl-fluorinated hydrocarbons and ketone-containing compounds, and mixtures thereof. Examples of solvents include, but are not limited to, cyclopentanone, cyclohexanone, lactate esters such as ethyl lactate, alkylene glycol alkyl ethers such as ethylene glycol methyl ether, dialkylene glycol dialkyl ethers such as diethylene glycol dimethyl ether, alkylene glycol alkyl ether esters such as propylene glycol methyl ether acetate, alkylene glycol ether esters such as ethylene glycol ether acetate, alkylene glycol monoalkyl esters such as methyl cellosolve, butyl acetate, 2-ethoxyethanol, trifluoromethylbenzene and ethyl 3-ethoxypropionate. Typically, solvents for silsesquioxane resins include, but are not limited to cyclopentanone (CP), propylene glycol methyl ether acetate (PGMEA), ethyl lactate (EL), methyl isobutyl ketone (MIBK), methyl ethyl ketone (MEK), ethyl 3-tethoxypropionate, 2-heptanone or methyl n-amyl ketone (MAK), and/or any their mixtures. The amount of solvent is typically present at 10 to 95 wt % of the total composition (i.e. (A), (B), and (C), alternatively, 30 to 60 wt % of the total composition.

Additives (D) may be optionally used in the photo sensitive composition. For example, if the photo sensitive composition is used as a positive photoresist, then the composition may include photo sensitizer, acid-diffusion controllers, surfactants, dissolution inhibitors, cross-linking agents, sensitizers, halation inhibitors, adhesion promoters, storage stabilizers, anti-foaming agents, coating aids, plasticizers, among others. The additive would be similar for both the positive and negative resist. An example of photo sensitizer is ITX (Isopropylthioxanthone). Typically, the sum of all additives (not including the acid generator) will comprise less than 10 percent of the solids included in the photoresist composition, alternatively less than 5 percent.

Another embodiment of the instant invention is a process for generating a resist image on a substrate. The process comprises the steps of: (a) coating a substrate with a film comprising a photo sensitive composition that can be used as both positive and negative photo resist comprising (i) a siloxane resin composition comprising 0 to 95 mole present of R¹SiO_{3/2} siloxane units, 0 to 95 mole percent of R²SiO_{3/2} siloxane units, and 5 to 99.9 mole percent of (R³O)_{b}SiO_{(4-b)/2} siloxane units wherein R¹ is hydrogen, an alkyl group containing 1 to 20 carbon atoms, or an aromatic group containing 1 to 20 carbon atoms, R² is a fluoroalkyl group containing 1 to 20 carbon atoms, R³ is independently selected from the group consisting of branched alkyl groups containing 3 to 30 carbon atoms, b has a value of 1 to 3, and wherein the siloxane resin composition the siloxane resin contains a molar ratio of R¹SiO_{3/2}+R²SiO_{3/2} siloxane units to (R³O)_{b}SiO_{(4-b)/2} siloxane units of 1:99 to 99:1 and wherein the sum of R¹SiO_{3/2} siloxane units, R²SiO_{3/2} siloxane units, and (R³O)_{b}SiO_{(4-b)/2} siloxane units is at least 50 mole percent of the total siloxane units in the resin composition; (ii) a photo acid generator (PAG); and (iii) an organic solvent; (b) imagewise exposing the film to radiation to produce an exposed film; and (c) developing the exposed film to produce an image.

Step (a) involves coating the substrate with a resist film comprising the resist composition. Suitable substrates are ceramic, metallic or semiconductive, and preferred substrates are silicon-containing, including, for example, silicon dioxide, silicon nitride, silicon oxynitride, silicon carbide, and silicon oxycarbide. The substrate may or may not be coated with an organic or anti-reflective underlayer prior to deposition of the resist composition. Alternatively, a bilayer substrate may be employed wherein a photoresist composition of the invention forms an upper photoresist layer (i.e., the imaging layer) on top of a bilayer substrate comprised of a base layer and underlayer that lies between the upper photoresist layer and the base layer. The base layer of the bilayer substrate is comprised of a suitable substrate material, and the underlayer of the bilayer substrate is comprised of a material that is highly absorbing at the imaging wavelength and compatible with the imaging layer. Conventional underlayers include cross-linked poly(4-hydroxystyrene), polyesters, polyacrylates, polymethacrylates, fluorinated polymers, cyclic-olefin polymers and the like including diazonapthoquinone (DNQ)/novolak resist material.

The surface of the coated or uncoated, single or bilayer substrate is typically cleaned by standard procedures before the resist film is deposited thereon. The resist film can be coated on the substrate using techniques known in the art, such as spin or spray coating, or doctor blading. Typically, the resist film is dried before the resist film is exposed to radiation, by heating to a temperature in the range of 30° C. to 150° C. for a short period of time (e.g. 20 to 90 seconds), typically on the order of approximately 1.0 minute. The resulting dried film has a thickness of 0.01 to 5.0 microns, alternatively 0.02 to 2.5 microns, alternatively 0.05 to 1.0 microns, and alternatively 0.10 to 0.20 microns.

The resist film is then (b) imagewise exposed to radiation, i.e., UV, X-ray, e-beam, EUV, or the like. Typically, ultraviolet radiation having a wavelength of 157 nm to 365 nm is used alternatively ultraviolet radiation having a wavelength of 157 nm or 193 nm is used. Suitable radiation sources include mercury, mercury/xenon, and xenon lamps. The preferred radiation source is a KrF excimer laser or a F₂ excimer laser. At longer wavelength radiation is used, e.g., 365 nm, it is suggested to add a sensitizer to the photoresist composition to enhance absorption of the radiation. Full exposure of the photoresist composition is typically achieved with less than 100 mJ/cm² of radiation, alternatively with less than 50 mJ/cm² of radiation.

Upon exposure to radiation, the radiation is absorbed by the acid generator in the photoresist composition to generate free acid. When the photoresist composition is a positive photoresist, upon heating, the free acid causes cleavage of the acid dissociable groups that are present in the photoresist composition and also limited crosslinking reaction not to the extent that cause the material not soluble in developer solution. When the photoresist composition is a negative photoresist, the free acid causes the crosslinking reaction of the silsesquioxane resin, thereby forming insoluble areas of exposed photoresist. After the photoresist composition has been exposed to radiation, the photoresist composition is typically heated to a temperature in the range of 30° C. to 200° C. for a short period of time, on the order of approximately 1 minute.

The exposed film is (c) developed with a suitable developer solution to produce an image. Suitable developer solutions typically are either organic solvent or an aqueous base solution, preferably an organic solvent. One skilled in the art will be able to select the appropriate developer solution. Commonly used organic solvent based developer include hydrocarbons, ethers, esters and fluorocarbons such as toluene, PMEGA, DMEGA, ethyl acetate, butyl acetate, MIBK, trifluorobenzene. Standard industry developer solutions contain bases such as tetramethylammonium hydroxide (TMAH), choline, sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, pyrrole, piperidine, 1,8-diazabicyclo-[5.4.0]-7-undecene, and 1,5-diaza bicyclo-[4.3.0]-5-nonene. In positive photoresist applications, the exposed areas of the photoresist will be soluble, leaving behind the unexposed areas. In negative photoresist, the converse is true, i.e., the unexposed regions will be soluble to the developer while the exposed regions will remain. After the exposed film has been developed, the remaining resist film (“pattern”) is typically washed with water to remove any residual developer solution.

The pattern may then be transferred to the material of the underlying substrate. In coated or bilayer photoresists, this will involve transferring the pattern through the coating that may be present and through the underlayer onto the base layer. In single layer photoresists the transfer will be made directly to the substrate. Typically, the pattern is transferred by etching with reactive ions such as oxygen, plasma, and/or oxygen/sulfurdioxide plasma. Suitable plasma tools include, but are not limited to, electron cyclotron resonance (ECR), helicon, inductively coupled plasma, (ICP) and transmission-coupled plasma (TCP) system. Etching techniques are well known in the art and one skilled in the art will be familiar with the various commercially available etching equipment.

Thus, the photoresist compositions of the invention can be used to create patterned material layer structures such as metal wiring lines, contact holes or vias, insulation sections (e.g., damascene trenches or shallow trench isolation), trenches for capacitor structures, etc. as might be used in the design of integrated circuit devices.

### EXAMPLES

The following non-limiting examples are provided so that one skilled in the art may more readily understand the invention. In the Examples weights are expressed as grams (g). Molecular weight is reported as weight average molecular weight (M_{w}) and number average molecular weight (Mₙ) determined by Gel Permeation Chromatography. Analysis of the siloxane resin composition was done using ²⁹Si and ¹³C nuclear magnetic resonance (NMR).

Resins having the formula (R¹SiO_{3/2})ₓ(R²SiO_{3/2})_{y}(R³OSiO_{3/2})_{z} were synthesized by hydrolysis and condensation of (AcO)₂Si(OR³)₂, R¹Si(OMe)₃ and R²Si(OMe)₃, where R¹ is methyl or phenyl; R² is —CH₂CH₂CF₃ or —CH₂CH₂(CF₂)₅CF₃, and R³ is a tert-butyl (t-Bu) group. The reactions were carried out in toluene solution catalyzed using acetic acid generated in situ. Materials were isolated as a toluene solution or solvent free solid/gum.

### Example 1: Synthesis of (PhSiO_{3/2})_{0.69}(t-buOSiO_{3/2})_{0.31}

This example illustrates the formation of a siloxane resin composition where R¹ is phenyl, R³ is a t-butyl group. Samples of 119 g of PhSi(OMe)₃ and 117.2 g of (AcO)₂Si(OtBu)₂ were mixed with 133 g of toluene in a three-neck flask equipped with a mechanical stir, a thermal couple and an addition funnel under a nitrogen atmosphere. Deionized water (37.5 g) was added dropwise to the reaction flask and the mixture was stirred at 64° C. for 1 hour. The solvent was removed using a rotary evaporator at 50° C. under reduced pressure (0-2 mTorr) to yield a viscous oil, which was immediately dissolved into 150 g of toluene. The volatile materials were evaporated using a rotary evaporator at the same conditions. The same process was repeated with another 100 g of toluene to remove residual acetic acid. The material in the flask was then dissolved into 300 g of toluene, charged into a three neck flask equipped with a mechanical stir, a thermal couple, and heated in refluxing toluene at 110° C. to continuously remove water using a dean-stark condenser for 30 minutes. The solution was filtered and the solvent removed by evaporation to yield the siloxane resin product, 48% solid in toluene. ²⁹Si NMR analysis show a composition of (PhSiO_{3/2})_{0.69}(t-BuOSiO_{3/2})_{0.31}

### Example 2: Synthesis of (PhSiO_{3/2})_{0.44}(CF₃CH₂CH₂SiO_{3/2})_{0.20}(t-buOSiO_{3/2})_{0.36}

This example illustrates the formation of a siloxane resin compositions where R¹ is phenyl, R² is —CH₂CH₂CF₃, R³ is a tert-butyl group. Samples of 80.0 g of PhSi(OMe)₃, 44.4 g of CF₃CH₂CH₂Si(OMe)₃, were mixed with 130 g of toluene in a three neck flask equipped with a mechanical stir, a thermal couple and addition funnel under a nitrogen atmosphere. Deionized water (37.3 g) was then added to the flask, 117.2 g of (AcO)₂Si(OtBu)₂ was then added dropwise into the mixture. The temperature rose to 37° C. after addition of (AcO)₂Si(OtBu)₂. The mixture was then heated to 59° C. and stirred at for 1 hour. The solvent was removed using a rotary evaporator at 50° C. under reduced pressure (0-2 mTorr) to yield a siloxane resin as a viscous oil, which was immediately dissolved into 100 g of toluene. The volatile materials were evaporated using a rotary evaporator at the same conditions. The same process was repeated with another 100 g of toluene to remove residual acetic acid. The resin was then dissolved into 300 g of toluene, charged into a three neck flask equipped with a mechanical stir, a thermal couple, and heated in refluxing toluene at 107° C. to continuously remove water using a dean-stark condenser for 30 minutes. The solution was cooled to room temperature and filtered to yield a resin product with 51.8% solid in toluene. GPC analyses of the product show M_{w}: 9140 and Mₙ: 3490. ²⁹SiNMR and ¹³C NMR analyses show a composition of (PhSiO_{3/2})_{0.44}(CF₃CH₂CH₂SiO_{3/2})_{0.20}(t-buOSiO_{3/2})_{0.36}

### Example 3: Synthesis of (PhSiO_{3/2})_{0.33}(CF₃(CF₂)₅CH₂CH₂SiO_{3/2})_{0.24}(t-buOSiO_{3/2})_{0.43}

This example illustrates the formation of a siloxane resin compositions where R¹ is phenyl, R² is —CH₂CH₂(CF₂)₅CF₃, R₃ is a t-butyl group. Samples of 80.3 g of PhSi(OMe)₃, 65.5 g of CF₃(CF₂)₅CH₂CH₂Si(OMe)₃, were mixed with 133 g of toluene in a three neck flask equipped with a mechanical stir, a thermal couple and addition funnel under an argon atmosphere. Deionized water (37.5 g) was then added all together to the flask, 117.2 g of (AcO)₂Si(OtBu)₂ was then added dropwise into the mixture. The temperature rose to 41° C. after addition of (AcO)₂Si(OtBu)₂. The mixture was then heated to 64° C. and stirred at for 1 hour. The solvent was removed using a rotary evaporator at 50° C. under reduced pressure (0-2 mTorr) to yield a siloxane resin as a viscous oil, which was immediately dissolved into 150 g of toluene. The volatile materials were evaporated using a rotary evaporator at the same conditions. The same process was repeated with another 100 g of toluene to remove residual acetic acid. The final resin was then dissolved into 300 g of toluene, charged into a three neck flask equipped with mechanical stir, thermal couple, heated in refluxing toluene at 110° C. to continuously remove water using a dean-stark condenser for 30 minutes. The solution was cooled to room temperature and was then filtered, which yielded the siloxane resin product with 43% solid in toluene. GPC analyses of the product show Mw: 11,600 and Mn: 4,510. ²⁹SiNMR and ¹³C NMR analyses show a composition of (PhSiO_{3/2})_{0.33}(CF₃(CF₂)₅CH₂CH₂SiO_{3/2})_{0.24}(t-buOSiO_{3/2})_{0.43}.

### Example 4. Formation of Patterned Structures from Example 1

A 100 g of resin solution (48% solid) prepared in Example 1 was mixed with 0.48 g of CPI 300 catalyst (a sulfonium salted purchased from Nagase). The solution was filtered through 0.45 micronmeter syringe filter and used for patterning evaluation (Sample 1).

### Positive Photoresist

15 grams of Sample 1 was spin coated on a 6″ silicon wafer @ 1000 RPM, 500 RPM/s, for 10 seconds. An 80° C. hot plate bake was then applied for 2 minutes to remove residual solvent. Contact masked lithography was utilized with a positive resist mask where expected patterned areas are covered by bronze on a soda lime plate. A UV patterning dose of 300 mJ/cm² was applied using a high pressure mercury arc lamp. After UV irradiation, the sample was hot plate baked at 130° C. for 2 minutes. After hot plate baking, the sample was immersed in toluene, to remove the UV irradiated portion of the sample. FIG. 1 shows top down microscope images of the formed 40 micron structures.

### Negative Photoresist

15 grams of Sample 1 was spin coated on a 6″ silicon wafer @ 1000 RPM, 500 RPM/s, for 10 seconds. An 80° C. hot plate bake was then applied for 2 minutes to remove residual solvent. Contact masked lithography was utilized with a negative resist mask where expected material removal areas are covered by bronze on a soda lime plate. A UV patterning dose of 2000 mJ/cm² was applied using a high pressure mercury arc lamp. After UV irradiation, the entire sample was UV irradiated with a blanket cure dose of 300 mJ/cm² using a UVA mercury bulb. After UV irradiation, the sample was hot plate baked at 80° C. for 2 minutes, then 130° C. for 30 seconds. After hot plate baking, the sample was immersed in toluene, to remove the portion of the sample that was subjected to low amounts of UV radiation while the material with high dose of UV radiation formed the polymer structure. FIG. 2 shows images of the formed structures, ranging from 20 micron-50 micron in size.

### Example 5. Formation of Patterned Structures from Example 2

97 g of resin solution (51.8% solid) prepared in Example 2 was mixed with 1.0 g of CPI 300 catalyst. The solution was filtered through 0.45 micronmeter syringe filter and used for patterning evaluation (Sample 2).

### Positive Photoresist

15 grams of Sample 2 was spin coated on a 6″ silicon wafer @ 1000 RPM, 500R RPM/S, for 10 seconds. An 80° C. hot plate bake was then applied for 2 minutes to remove residual solvent. Contact masked lithography was utilized with a positive resist mask where expected material removal areas are not covered by bronze on a soda lime plate. A UV patterning dose of 300 mJ/cm² was applied using a high pressure mercury arc lamp. After UV irradiation, the sample was hot plate baked at 150° C. for 20 seconds. After hot plate baking, the sample was immersed in toluene, to remove the portion of the sample that was subjected UV radiation while the material that had no UV radiation formed the polymer structure. FIG. 3 shows images of the formed 35 micron waveguide structures.

### Negative Photoresist

15 grams of Sample 2 was spin coated on a 6″ silicon wafer @ 1000 RPM, 500 RPM/s, for 10 seconds. An 80° C. hot plate bake was then applied for 2 minutes to remove residual solvent. Contact masked lithography was utilized with a negative resist mask where expected material removal areas are covered by bronze on a soda lime plate. A UV patterning dose of 4000 mJ/cm² was applied using a high pressure mercury arc lamp. After UV irradiation, the sample was hot plate baked at 130° C. for 4 minutes. After hot plate baking, the sample was immersed in toluene, to remove the portion of the sample that was subjected to no UV radiation while the material with high dose of UV radiation formed the polymer structure. FIG. 4 shows images of the formed structures, ranging from 25 micron-100 micron in size.

### Example 6. Formation of Patterned Structures from Example 3

100 g resin solution (43% solid) prepared in Example 3 was mixed with 0.43 g of CPI 300 catalyst. The solution was filtered through 0.45 micron meter syringe filter and used for patterning evaluation (Sample 3).

### Positive Photoresist

15 grams of Sample 3 was spin coated on a 6″ silicon wafer @ 1000 RPM, 500R RPM/s, for 10 seconds. An 80° C. hot plate bake was then applied for 2 minutes to remove residual solvent. Contact masked lithography was utilized with a positive resist mask where expected material removal areas are not covered by bronze on a soda lime plate. A UV patterning dose of 300 mJ/cm² was applied using a high pressure mercury arc lamp. After UV irradiation, the sample was hot plate baked at 150° C. for 20 seconds. After hot plate baking, the sample was immersed in toluene, to remove the portion of the sample that was subjected UV radiation while the material that had no UV radiation formed the polymer structure. Figure shows images of the formed 35 micron waveguide structures.

### Negative Photoresist

15 grams of Sample 3 was spin coated on a 6″ silicon wafer @ 1000 RPM, 500R RPM/s, for 10 seconds. An 80° C. hot plate bake was then applied for 2 minutes to remove residual solvent. Contact masked lithography was utilized with a negative resist mask where expected material removal areas are covered by bronze on a soda lime plate. A UV patterning dose of 4000 mJ/cm² was applied using a high pressure mercury arc lamp. After UV irradiation, the sample was hot plate baked at 150° C. for 4 minutes. After hot plate baking, the sample was immersed in toluene, to remove the portion of the sample that was subjected no UV radiation while the material with high dose of UV radiation formed the polymer structure. Figure shows images of the formed structures, ranging from 25 micron-100 micron in size as well as cured material outside the areas that receive any amounts of UV radiation. The images in this example suggest that high doses of UV radiation (negative resist) and no UV radiation (thermal curing) allow polymerization while areas with low doses of UV radiation (positive resist) develop away.

In a separate experiment, the example above was repeated with adding a 300 mJ/cm² UV blanket dose after the patterning to prevent curing of unexposed region during UV patterning. 15 grams of Sample 3 was spin coated on a 6″ silicon wafer @ 1000 RPM, 500R RPM/s, for 10 seconds. An 80° C. hot plate bake was then applied for 2 minutes to remove residual solvent. Contact masked lithography was utilized with a negative resist mask where expected material removal areas are covered by bronze on a soda lime plate. A UV patterning dose of 4000 mJ/cm² was applied using a high pressure mercury arc lamp. After UV irradiation, the entire sample was UV irradiated with a blanket cure dose of 300 mJ/cm² using a UVA mercury bulb. After UV irradiation, the sample was hot plate baked at 150° C. for 4 minutes. After hot plate baking, the sample was immersed in toluene, to remove the portion of the sample that was subjected low amounts of UV radiation while the material with high dose of UV radiation formed the polymer structure. Figure shows images of the formed structures, ranging from 5 micron-100 micron in size. Comparing the images in Figure and Figure, it is observed that utilization of the positive resist properties of the material by low UV blanket dose removes the thermally cured portions of material on the wafer while the high UV dose (negative resist property) areas polymerize the material.

1. A photo sensitive composition that can be used as both positive and negative photo resist comprising:
(A) a siloxane resin composition comprising 0 to 95 mole present of R¹SiO_{3/2} siloxane units, 0 to 95 mole percent of R²SiO_{3/2} siloxane units, and 1 to 99.9 mole percent of (R³O)_{b}SiO_{(4-b)/2} siloxane units wherein R¹ is an alkyl group containing 1 to 20 carbon atoms, or phenyl, R² is selected from —(CH₂)ₘCF₃ and —(CH₂)ₘ(CF₂)ₙCF₃ where m has a value of from 1 to 19 and n has a value of from 1 to 18 and where the total value of m+n is from 1 to 19, R³ is independently selected from the group consisting of branched alkyl groups containing 3 to 30 carbon atoms, b has a value of 1 to 3, and wherein the siloxane resin composition the siloxane resin contains a molar ratio of R¹SiO_{3/2}+R²SiO_{3/2} siloxane units to (R³O)_{b}SiO_{(4-b)/2} siloxane units of 1:99 to 99:1 and wherein the sum of R¹SiO_{3/2} siloxane units, R²SiO_{3/2} siloxane units, and (R³O)_{b}SiO_{(4-b)/2} siloxane units is at least 5 mole percent of the total siloxane units in the resin composition;
(B) a photo acid generator (PAG); and
(C) an organic solvent.

2. A composition according to claim 1, where R¹ is selected from methyl, phenyl, or mixtures thereof.

3. A composition according to claim 1, wherein R² is —(CH₂)₂CF₃ or —(CH₂)₂(CF₂)₅CF₃.

4. A composition according to claim 1, wherein R³ is a tertiary alkyl group having 4 to 18 carbon atoms.

5. A composition according to claim 1, wherein R³ is tertiary (tert) butyl group.

6. A composition according to claim 1, wherein (B) is a sulfonated salt.

7. A composition according to claim 1 wherein (B) is a sulfonated salt containing perfluorinated methide anions.

8. A composition according to claim 5, wherein (B) is a sulfonated salt containing perfluorinated methide anions.

9. A composition according to claim 1, wherein (C) is selected from cyclopentanone (CP), propylene glycol methyl ether acetate (PGMEA), ethyl lactate (EL), methyl isobutyl ketone (MIBK), methyl ethyl ketone (MEK), ethyl 3-tethoxypropionate, 2-heptanone or methyl n-amyl ketone (MAK), or any their mixtures thereof.

10. A composition according to claim 5, wherein (C) is selected from cyclopentanone (CP), propylene glycol methyl ether acetate (PGMEA), ethyl lactate (EL), methyl isobutyl ketone (MIBK), methyl ethyl ketone (MEK), ethyl 3-tethoxypropionate, 2-heptanone or methyl n-amyl ketone (MAK), or any their mixtures thereof.

11. A composition according to claim 8, wherein (C) is selected from cyclopentanone (CP), propylene glycol methyl ether acetate (PGMEA), ethyl lactate (EL), methyl isobutyl ketone (MIBK), methyl ethyl ketone (MEK), ethyl 3-tethoxypropionate, 2-heptanone or methyl n-amyl ketone (MAK), or any their mixtures thereof.

12. A composition according to claim 1, where in the composition further comprises photosensitizers, acid-diffusion controllers, surfactants, dissolution inhibitors, cross-linking agents, sensitizers, halation inhibitors, adhesion promoters, storage stabilizers, anti-foaming agents, coating aids, plasticizers, or mixtures thereof.

13. A process for generating a resist image on a substrate comprising the steps of:
(a) coating a substrate with a film comprising a photo sensitive composition that can be used as both positive and negative photo resist comprising:
(i) a siloxane resin composition comprising 0 to 95 mole present of R¹SiO_{3/2} siloxane units, 0 to 95 mole percent of R²SiO_{3/2} siloxane units, and 5 to 99.9 mole percent of (R³O)_{b}SiO_{(4-b)/2} siloxane units wherein R¹ is hydrogen, an alkyl group containing 1 to 20 carbon atoms, or phenyl, R² is selected from —(CH₂)ₘCF₃ and —(CH₂)ₘ(CF₂)ₙCF₃ where m has a value of from 1 to 19 and n has a value of from 1 to 18 and where the total value of m+n is from 1 to 19, R³ is independently selected from the group consisting of branched alkyl groups containing 3 to 30 carbon atoms, b has a value of 1 to 3, and wherein the siloxane resin composition the siloxane resin contains a molar ratio of R¹SiO_{3/2}+R²SiO_{3/2} siloxane units to (R³O)_{b}SiO_{(4-b)/2} siloxane units of 1:99 to 99:1 and wherein the sum of R¹SiO_{3/2} siloxane units, R²SiO_{3/2} siloxane units, and (R³O)_{b}SiO_{(4-b)/2} siloxane units is at least 50 mole percent of the total siloxane units in the resin composition;
(ii) a photo acid generator (PAG); and
(iii) an organic solvent;
(b) imagewise exposing the film to radiation to produce an exposed film; and
(c) developing the exposed film to produce an image.

14. A process according to claim 13, wherein the substrate is selected from silicon dioxide, silicon nitride, silicon oxynitride, silicon carbide, or silicon oxycarbide.

15. A process according to claim 13, wherein process further comprises heating the film to a temperature in the range of 30° C. to 200° C. after step (b).

16. the composition according to claim 1, wherein R¹ is phenyl.
